(19) United States
(12) Patent Application Publication
(10) Pub. No.: US 2016/0044783 A1
(43) Pub. Date: Feb. 11, 2016

(54) PRINTED WIRING BOARD, METHOD FOR MANUFACTURING THE SAME AND SEMICONDUCTOR PACKAGE

(71) Applicant: IBIDEN CO., LTD., Ogaki-shi (JP)

(72) Inventors: Toshiki Furutani, Ogaki-shi (JP); Shunsuke Sakai, Ogaki-shi (JP); Yasushi Inagaki, Ogaki-shi (JP)

(73) Assignee: IBIDEN CO., LTD., Ogaki-shi (JP)

(21) Appl. No.: 14/821,961

(22) Filed: Aug. 10, 2015

(30) Foreign Application Priority Data
Aug. 8, 2014 (JP) 2014-162619

(51) Int. Cl. H05K 1/11; H05K 1/18; H05K 1/14; H05K 3/46; H05K 1/02

(52) U.S. Cl. CPC H05K 1/11; H05K 3/4682; H05K 1/0298; H05K 1/144; H05K 1/185; H05K 2201/068

(57) ABSTRACT

A printed wiring board includes a wiring conductor layer having a first surface, conductor posts formed on a second surface of the wiring conductor layer on the opposite side with respect to the first surface, and a resin insulating layer embedding the wiring conductor layer such that the first surface of the wiring conductor layer is recessed with respect to a first surface of the resin insulating layer and exposed on the first surface of the resin insulating layer and covering side surfaces of the conductor posts such that an end surface of each of the conductor posts is protruding from a second surface of the resin insulating layer on the opposite side with respect to the first surface of the resin insulating layer.

### CROSS-REFERENCE TO RELATED APPLICATIONS

The present application is based upon and claims the benefit of priority to Japanese Patent Application No. 2014-162619, filed Aug. 8, 2014, the entire contents of which are incorporated herein by reference.

### BACKGROUND OF THE INVENTION

1. Field of the Invention

The present invention relates to a printed wiring board and a method for manufacturing the printed wiring board and relates to a semiconductor package. More specifically, the present invention relates to a printed wiring board and a method for manufacturing the printed wiring board, the printed wiring board having a conductor post that extends from a wiring conductor layer that is formed on one side to the other side, and relates to a semiconductor package that includes the printed wiring board.

2. Description of Background Art

Japanese Patent Laid-Open Publication No. HEI 10-13028 describes a single-sided circuit substrate in which a conductor circuit (conductor layer) is formed on one side of an insulating substrate by patterning a metal foil, a through hole penetrates through the insulating substrate from the other side of the insulating substrate toward the conductor circuit, a conductor post is formed by filling the through hole with a conductive paste, and a front end part of the conductor post that protrudes from the other side of the insulating substrate is used as a connecting part that connects to another insulating substrate or the like. The entire contents of this publication are incorporated herein by reference.

### SUMMARY OF THE INVENTION

According to one aspect of the present invention, a printed wiring board includes a wiring conductor layer having a first surface, conductor posts formed on a second surface of the wiring conductor layer on the opposite side with respect to the first surface, and a resin insulating layer embedding the wiring conductor layer such that the first surface of the wiring conductor layer is recessed with respect to a first surface of the resin insulating layer and exposed on the first surface of the resin insulating layer and covering side surfaces of the conductor posts such that an end surface of each of the conductor posts is protruding from a second surface of the resin insulating layer on the opposite side with respect to the first surface of the resin insulating layer.

According to another aspect of the present invention, a semiconductor package includes a printed wiring board, a first semiconductor component mounted on a surface of the printed wiring board, and a substrate mounted on the surface of the printed wiring board and having a bump structure formed on a surface of the substrate facing the printed wiring board. The printed wiring board includes a wiring conductor layer having a first surface, conductor posts formed on a second surface of the wiring conductor layer on the opposite side with respect to the first surface, and a resin insulating layer embedding the wiring conductor layer such that the first surface of the wiring conductor layer is recessed with respect to a first surface of the resin insulating layer and exposed on the first surface of the resin insulating layer and covering side surfaces of the conductor posts such that an end surface of each of the conductor posts is protruding from a second surface of the resin insulating layer on the opposite side with respect to the first surface of the resin insulating layer, and the bump structure of the substrate is connected to the wiring conductor layer of the printed wiring board.

According to yet another aspect of the present invention, a method for manufacturing a printed wiring board includes forming a conductor layer having a pattern on a support plate, forming a conductor post on the conductor layer, forming a resin insulating layer on the conductor layer such that the resin insulating layer covers the entire exposed surface of the conductor layer and at least the entire side surface of the conductor post, removing a surface layer portion of the resin insulating layer on the opposite side with respect to the conductor layer such that an end portion of the conductor post protrudes from a surface of the resin insulating layer, and separating the support plate from the conductor layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is an explanatory cross-sectional view of a printed wiring board according to an embodiment of the present invention;

FIG. 2 is an enlarged view of a wiring conductor layer and a conductor post of the printed wiring board illustrated in FIG. 1;

FIG. 3 is a cross-sectional view of the wiring conductor layer and the conductor post of FIG. 1, on each of which a surface protection film is formed;

FIG. 4A illustrates an example of a layout of conductor posts of a printed wiring board according to an embodiment of the present invention;

FIG. 4B illustrates another example of a layout of conductor posts of a printed wiring board according to an embodiment of the present invention;

FIG. 5A is an explanatory diagram of a process of an example of a method for manufacturing the printed wiring board illustrated in FIG. 1;

FIG. 5B is an explanatory diagram of a process of the example of the method for manufacturing the printed wiring board illustrated in FIG. 1;

FIG. 5C is an explanatory diagram of a process of the example of the method for manufacturing the printed wiring board illustrated in FIG. 1;

FIG. 5D is an explanatory diagram of a process of the example of the method for manufacturing the printed wiring board illustrated in FIG. 1;

FIG. 5E is an explanatory diagram of a process of the example of the method for manufacturing the printed wiring board illustrated in FIG. 1;

FIG. 5F is an explanatory diagram of a process of the example of the method for manufacturing the printed wiring board illustrated in FIG. 1;

FIG. 5G is an explanatory diagram of a process of the example of the method for manufacturing the printed wiring board illustrated in FIG. 1;

FIG. 5H is an explanatory diagram of a process of the example of the method for manufacturing the printed wiring board illustrated in FIG. 1;

FIG. 5I is an explanatory diagram of a process of the example of the method for manufacturing the printed wiring board illustrated in FIG. 1;

FIG. 5J is an explanatory diagram of a process of the example of the method for manufacturing the printed wiring board illustrated in FIG. 1;

FIG. 6A is an explanatory diagram of a process of another example of the method for manufacturing the printed wiring board illustrated in FIG. 1;

FIG. 6B is an explanatory diagram of a process of the other example of the method for manufacturing the printed wiring board illustrated in FIG. 1;

FIG. 6C is an explanatory diagram of a process of the other example of the method for manufacturing the printed wiring board illustrated in FIG. 1;

FIG. 6D is an explanatory diagram of a process of the other example of the method for manufacturing the printed wiring board illustrated in FIG. 1;

FIG. 7A is an explanatory diagram of a process of a method for manufacturing a printed wiring board that is further built up from the printed wiring board illustrated in FIG. 1;

FIG. 7B is an explanatory diagram of a process of the method for manufacturing the printed wiring board that is further built up from the printed wiring board illustrated in FIG. 1;

FIG. 7C is an explanatory diagram of a process of the method for manufacturing the printed wiring board that is further built up from the printed wiring board illustrated in FIG. 1;

FIG. 7D is an explanatory diagram of a process of the method for manufacturing the printed wiring board that is further built up from the printed wiring board illustrated in FIG. 1;

FIG. 8A is a cross-sectional view of a semiconductor package of an embodiment of the present invention;

FIG. 8B is a cross-sectional view illustrating an example in which the semiconductor package illustrated in FIG. 8A is filled with a mold resin; and

FIG. 8C is a cross-sectional view illustrating a state in which a second semiconductor component is mounted on the semiconductor package illustrated in FIG. 8B.

### DETAILED DESCRIPTION OF THE EMBODIMENTS

The embodiments will now be described with reference to the accompanying drawings, wherein like reference numerals designate corresponding or identical elements throughout the various drawings.

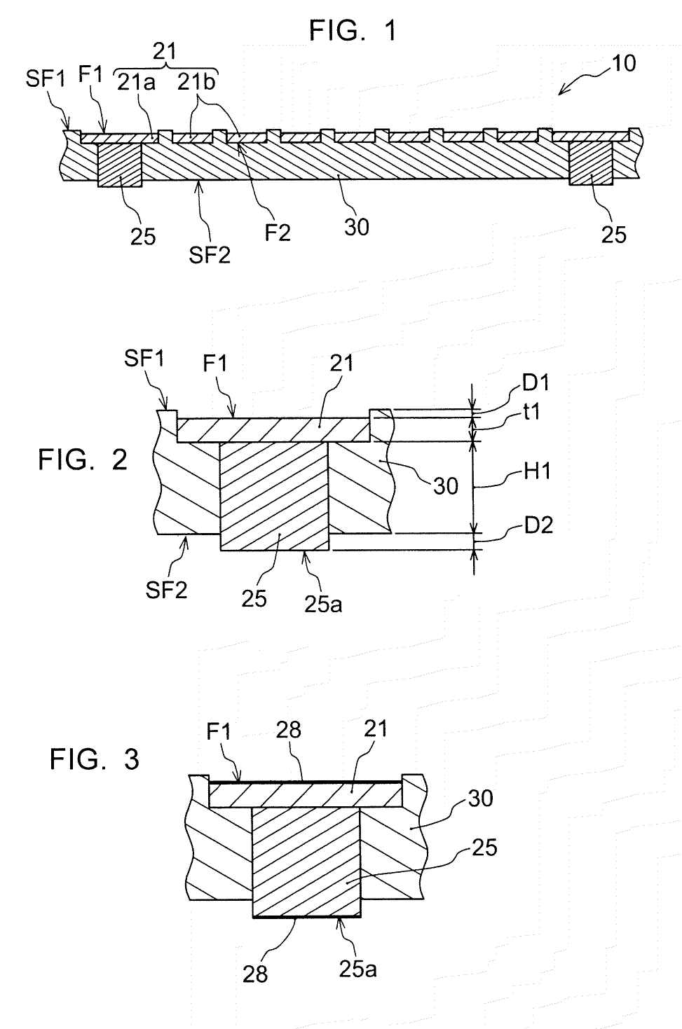

As illustrated in FIG. 1, a printed wiring board 10 according to an embodiment of the present invention (hereinafter, the printed wiring board is also simply referred to as the wiring board) includes: a wiring conductor layer 21 that has a first surface (F1) and a second surface (F2) that is on an opposite side of the first surface (F1); a conductor post 25 that is formed on the second surface (F2) of the wiring conductor layer 21; and a resin insulating layer 30 that has a first surface (SF1) and a second surface (SF2) that is on an opposite side of the first surface (SF1), embeds the wiring conductor layer 21 such that the first surface (F1) of the wiring conductor layer 21 is exposed to the first surface (SF1) side, and covers a side surface of the conductor post 25. In the present embodiment, the first surface (F1) of the wiring conductor layer 21 is recessed relative to the first surface (SF1) of the resin insulating layer 30. Further, an end surface (25a) of the conductor post 25 on an opposite side of the wiring conductor layer 21 is exposed to the second surface (SF2) side of the resin insulating layer 30 and protrudes from the second surface (SF2).

The entire wiring conductor layer 21 is embedded in the resin insulating layer 30 on the first surface (SF1) side such that the first surface (F1) of the wiring conductor layer 21 is exposed to the first surface (SF1) side of the resin insulating layer 30. That is, the wiring conductor layer 21 and the resin insulating layer 30 are in contact with each other not only at the second surface (F2) of the wiring conductor layer 21, but also at side surfaces of the wiring conductor layer 21, specifically, at side surfaces of a first pattern (21a) and a second pattern (21b) that are formed in the wiring conductor layer 21. Therefore, even when the first pattern (21a) and the second pattern (21b) are formed at fine pitches and an area of the second surface (F2) of the wiring conductor layer 21 is reduced, the adhesion between the wiring conductor layer 21 and the resin insulating layer 30 can be maintained. Further, by embedding the wiring conductor layer 21 in the resin insulating layer 30, the wiring board 10 can be formed thin.

As described above, the first pattern (21a) and the second pattern (21b) are formed in the wiring conductor layer 21. In the present embodiment, the first pattern (21a) is a wiring pattern that electrically connects to another printed wiring board (not illustrated in the drawings) that is connected to the wiring board 10 on the second surface (SF2) side of the resin insulating layer 30. Here, the other printed wiring board may be a motherboard of an electronic device or the like in which the wiring board 10 is used, or may be a laminated body of an insulating layer and a conductor layer, the laminated body and the wiring board 10 forming a multilayer wiring board. Further, the second pattern (21b) may be, for example, connection pads to which a semiconductor component (not illustrated in the drawings) or the like is connected. Further, a wiring pattern other than the first and second patterns (21a, 21b) may also be formed in the wiring conductor layer 21. For example, among electrodes of a semiconductor component that is connected to the second pattern (21b), one electrode that is electrically connected to outside is electrically connected to the first pattern (21a) and the conductor post 25 via a wiring pattern (not illustrated in the drawings) that is formed in the wiring conductor layer 21 so that the second pattern (21b) and the first pattern (21a) are connected.

As illustrated in FIG. 1, the conductor post 25 is formed on the second surface (F2) of the first pattern (21a) of the wiring conductor layer 21. The conductor post 25 extends from the second surface (F2) of the first pattern (21a) toward the second surface (SF2) side of the resin insulating layer 30. The end surface (25a) of the conductor post 25 is exposed to the second surface (SF2) side of the resin insulating layer 30. For example, as described above, the conductor post 25 electrically connects a predetermined electrode of the semiconductor component (not illustrated in the drawings) and the above-described other printed wiring board or the like, the semiconductor component being connected to the second pattern (21b). Therefore, a number of conductor posts 25 corresponding to a number of the electrodes of the semiconductor component (not illustrated in the drawings) may be provided along an outer periphery of the second surface (SF2) of the resin insulating layer 30 or over the entire second surface (SF2). As will be described later, a resist mask is formed in which a portion where a conductor post 25 is to be formed is removed, and the conductor post 25 is formed on the wiring conductor layer 21 that is exposed from the resist mask using a method such as electroplating. Therefore, this method for forming the conductor post 25 is different from a method in which a through hole is opened by irradiating laser to the resin insulating layer and the through hole is filled with a conductor. Therefore, different from a via conductor of a tapered shape having a large diameter on one side and a small diameter on the other, the conductor post 25 is formed in a shape of a column that has the same diameter on both sides, that is, the conductor post 25 is formed as a post that has a uniform diameter and vertically stands on the wiring conductor layer 21. Therefore, even when conductor posts 25 are thin due to being formed at a fine pitch, reliable electrical connection between the conductor posts 25 and the wiring conductor layer 21 can be obtained. In particular, the conductor posts 25 are directly formed on the wiring conductor layer 21 by electroplating. Therefore, without having residues of the insulating layer due to drilling left therebetween, highly reliable connection between the conductor posts 25 and the wiring conductor layer 21 can be obtained.

It is preferable that unevenness be formed on the side surface of the conductor post 25. This is because this can improve adhesion between the conductor post 25 and the resin insulating layer 30 (to be described later). From this point of view, it is preferable that unevenness (roughening) be formed also on the second surface (F2) and the side surface of the wiring conductor layer 21. The roughening, for example, can be formed by etching or the like using oxidation and reduction or the like.

The resin insulating layer 30 covers the side surface of the wiring conductor layer 21 and a portion of the second surface (F2) where a conductor post 25 is not formed, and also covers the side surface of the conductor post 25. The first surface (F1) of the wiring conductor layer 21 is exposed on the first surface (SF1) side of the resin insulating layer 30, and the end surface (25a) of the conductor post 25 is exposed on the second surface (SF2) side on the opposite side. A thickness of the resin insulating layer 30 is not particularly limited. However, from a point of view of having a certain degree of rigidity to allow easy handling while complying with a demand for thickness reduction in the wiring board 10, it is preferable that the thickness of the resin insulating layer 30 be about 100-200 μm.

As a material of the resin insulating layer 30, for example, a resin composition that does not contain a core material can be used. As the resin composition, an epoxy resin is preferably used. Further, an epoxy resin containing 30-80% by weight of an inorganic filler such as silica may also be used. Further, the material of the resin insulating layer 30 may also be a resin composition suitable to be supplied in a sheet form or a film form when the wiring board 10 is manufactured, or may also be a resin material for mold-molding suitable for a case where the resin insulating layer 30 is formed by mold-molding. When a resin material for mold-molding is selected, that the material of the resin insulating layer 30 has a thermal expansion coefficient of 6-25 ppm/° C. and an elastic modulus of 5-30 GPa is preferable in that a good flowability can be obtained in a mold during molding and an excessive stress does not occur after the molding at an interface with the wiring conductor layer 21 and at a part connecting to a semiconductor component (not illustrated in the drawings) or the like that is mounted on the first surface (SF1) side of the resin insulating layer 30. However, a material having a thermal expansion coefficient and an elastic modulus outside the above-described ranges may also be used for the resin insulating layer 30.

As illustrated in FIG. 1, the first surface (F1) of the wiring conductor layer 21 is positioned on the second surface (SF2) side more than the first surface (SF1) of the resin insulating layer 30 does, and is recessed relative to the first surface (SF1). In this way, the wiring conductor layer 21 is formed. Therefore, even when a semiconductor component (not illustrated in the drawings) on which electrodes are formed at a narrow pitch is connected to the second pattern (21b) or the like using bonding materials or the like, a portion of the resin insulating layer 30 between second patterns (21b) becomes a wall and a state can be prevented in which the bonding materials or the like become in contact with each other and cause electrical short circuiting to occur between adjacent second patterns (21b).

Further, the end surface (25a) of the conductor post 25 is flush with or protrudes from the second surface (SF2) of the resin insulating layer 30. When the wiring board 10 is further built up with similar structures, it is preferable that the end surface (25a) of the conductor post 25 be flush with the second surface (SF2) of the resin insulating layer 30. Further, when the wiring board 10 is used as an outermost layer and is connected to a motherboard (not illustrated in the drawings) or the like, that the end surface (25a) of the conductor post 25 protrudes from the second surface (SF2) of the resin insulating layer 30 allows the motherboard or the like to be easily connected. In order to make the end surface (25a) of the conductor post 25 flush with the second surface of the resin insulating layer 30, as will be described later, after the resin insulating layer is formed, the resin insulating layer is polished until the conductor post 25 is exposed. Therefore, by stopping the polishing at the point when the conductor post 25 is exposed by the polishing, the end surface (25a) of the conductor post 25 becomes flush with the second surface of the resin insulating layer 30. Further, by removing only the resin insulating layer by sandblasting or the like, the end surface (25a) of the conductor post 25 can be made to protrude from the second surface (SF2) of the resin insulating layer 30.

In the present embodiment, a distance from the second surface (SF2) of the resin insulating layer 30 to the end surface (25a) of the conductor post 25 is not particularly limited. However, the conductor post 25 is formed to protrude from the second surface (SF2) of the resin insulating layer 30, for example, for about 3-10 μm. By having such a protruding portion, the conductor post 25 can be easily connected to a motherboard or the like, and it is also possible to use a connection method in which a bonding material of copper-copper bonding or the like is not used. To prevent oxidation and the like, as will be described later, the end surface (25a) may be subjected to a surface treatment of Ni/Au, Ni/Pd/Au, Sn or the like.

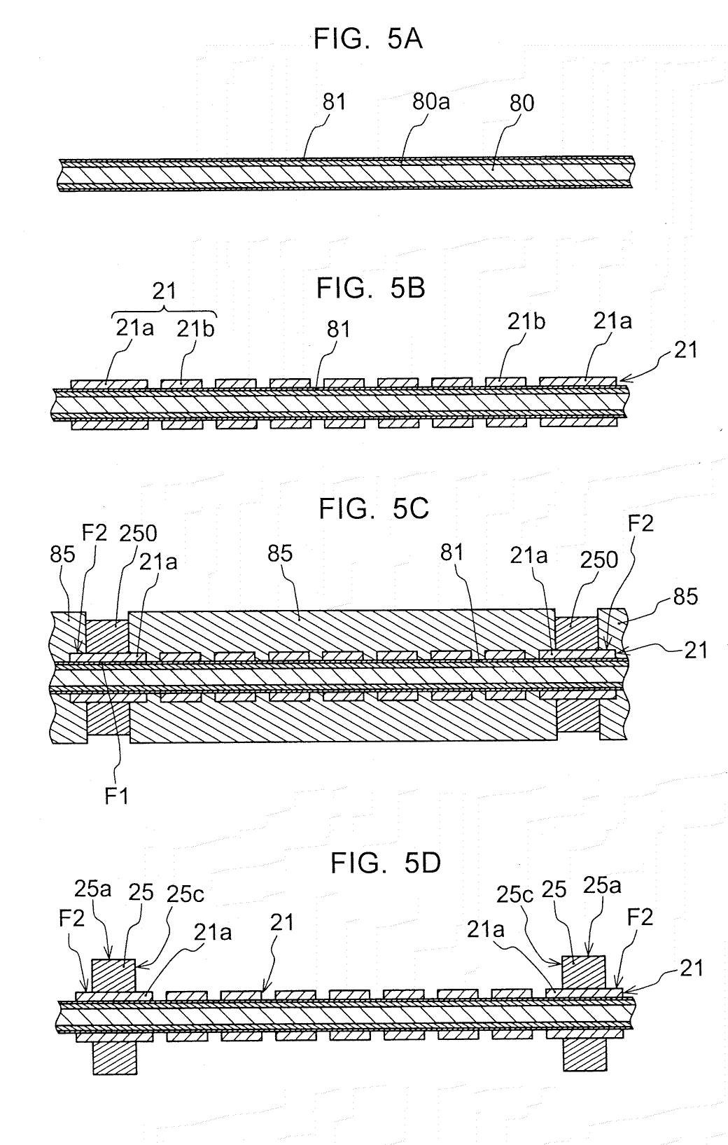

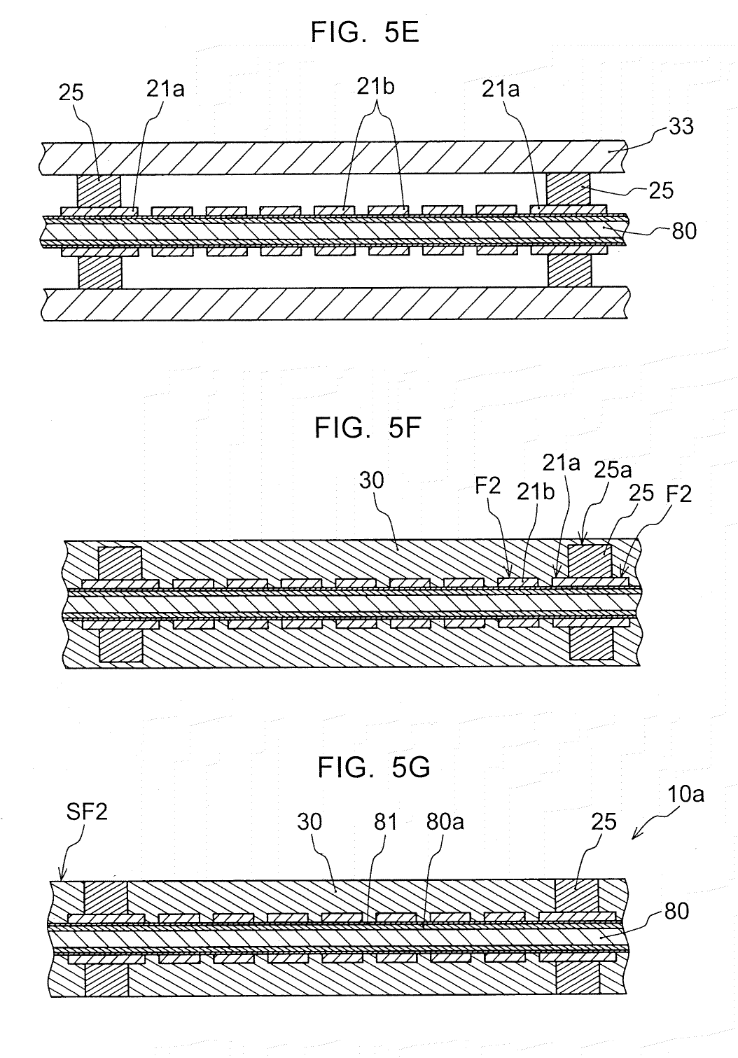

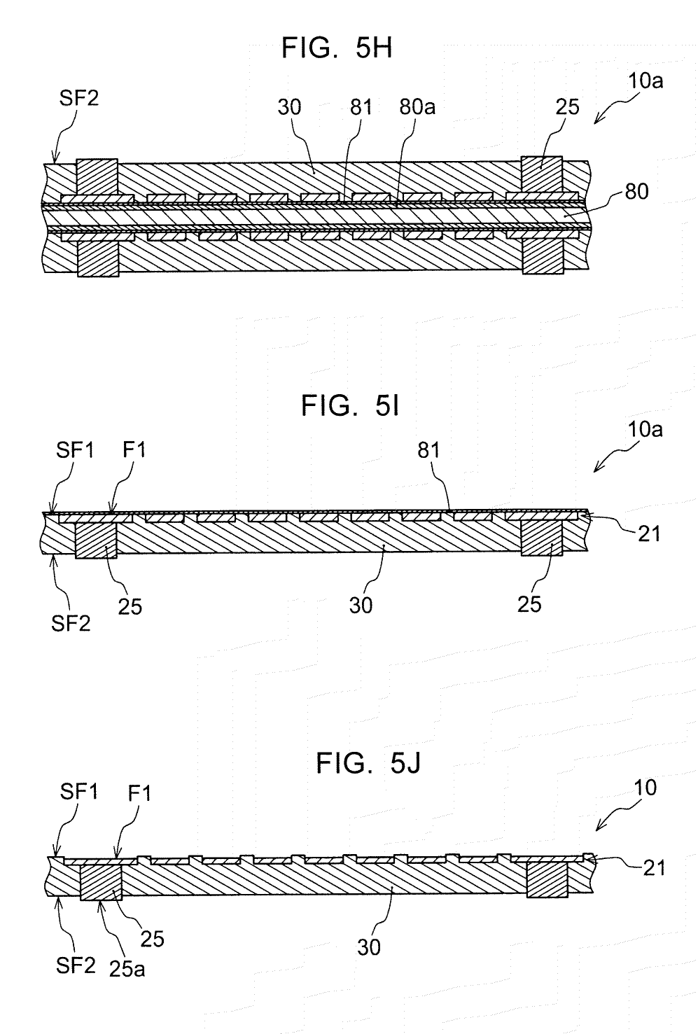

A method for forming the wiring conductor layer 21 and the conductor post 25 is not particularly limited. However, it is preferable that the wiring conductor layer 21 and the conductor post 25 be formed using an electroplating method that allows a metal film to be easily formed at a low cost. Further, other than the electroplating method, for example, the wiring conductor layer 21 may also be formed using an ink jet method or the like. Further, for example, the conductor post 25 may also be formed by forming in advance a conductor pin made of a conductive material in a shape of a circular cylinder or a quadrangular prism and connecting the conductor pin to the first pattern (21a). In a method for manufacturing the wiring board 10 (to be described later), the first surface (F1) of the wiring conductor layer 21 can be made recessed relative to the first surface (SF1) of the resin insulating layer 30 by continuing etching for a proper period of time even after a base metal foil 81 (see FIG. 5H) has completely dissolved when the base metal foil 81 is removed by etching. Further, in the etching process of the base metal foil 81, a surface of the conductor post 25 that is exposed to the second surface (SF2) side of the resin insulating layer 30 is masked and is exposed to an etching solution. Thereby, without etching the conductor post 25, a state is maintained in which the end surface (25a) is flush with the second surface (SF2) of the resin insulating layer 30. Thereafter, the resin insulating layer 30 is partially removed on the second surface (SF2) side by sandblasting or the like. Thereby, the end surface (25a) of the conductor post 25 can protrude from the second surface (SF2) of the resin insulating layer 21.

The material of which the wiring conductor layer 21 and the conductor post 25 are formed is not particularly limited. However, copper that allows easy formation of the wiring conductor layer 21 and the conductor post 25 by electroplating and has excellent conductivity is mainly used. However, the wiring conductor layer 21 and the conductor post 25 may also be formed of a material other than copper, such as a copper alloy or a conductive paste obtained in a paste form by mixing a conductive material and a resin composition.

Preferred examples of dimensions of the wiring conductor layer 21 and the conductor post 25 are described with reference to FIG. 2. A distance (D1) from the first surface (SF1) of the resin insulating layer 30 to the first surface (F1) of the wiring conductor layer 21 is 0.1-5 μm, for example. Setting the distance (D1) to such a length is preferable in that the period of time over which etching is continued after the metal foil 81 (see FIG. 5H) is removed does not become too long and that bonding materials or the like become in contact with each other between adjacent second patterns (21b) or the like can be prevented. A distance (D2) from the second surface (SF2) of the resin insulating layer 30 to the end surface (25a) of the conductor post 25 is 1-15 μm, for example. However, from a point of view that the above-described effect due to that the conductor post 25 protrudes from the second surface of the resin insulating layer 30 is significantly obtained and the formation of the conductor post 25 may require a too long period of time, it is most preferable that the distance (D2) be about 3-10 μm. Setting the distance (D2) to such a length is preferable in that it does not take a too long period of time to partially remove the resin insulating layer 30 on the second surface (SF2) side and the end surface (25a) protrudes from the second surface (SF2) of the resin insulating layer 30. From a point of view that the wiring conductor layer 21 can be formed in a relatively short period of time using an electroplating method while ensuring a certain conductivity, it is preferable that a thickness (t1) of the wiring conductor layer 21 be about 10-25 μm. A height (H1+D2) of the conductor post 25 is not particularly limited as long as it is a height that allows the wiring conductor layer 21 and a motherboard or the like on the second surface (SF2) side of the resin insulating layer 30 to be connected. However, for example, the height (H1+D2) is 50-150 μm. That the conductor post 25 is formed to have such a height is preferable in that the conductor post 25 can be applied to a resin insulating layer 30 having a thickness (H1) of about 100 μm. However, the distance (D1) from the first surface (SF1) of the resin insulating layer 30 to the first surface (F1) of the wiring conductor layer 21, the distance (D2) from the second surface (SF2) of the resin insulating layer 30 to the end surface (25a) of the conductor post 25, the thickness (t1) of the wiring conductor layer 21, and the thickness (H1) of the resin insulating layer 30 may respectively be distances or thicknesses that exceed or are below the above-described ranges.

As illustrated in FIG. 3, a surface protection film 28 may be formed on each of the first surface (F1) of the wiring conductor layer 21 and the end surface (25a) of the conductor post 25. Here, in addition to the meaning of a film that protects the wiring conductor layer 21 or the conductor post 25 against corrosion such as oxidation, the “surface protection film” also includes the meaning of a film that is formed on the first surface (F1) or the end surface (25a) in order to obtain a good bondability with a bonding material such as solder or a bonding wire. Examples of the surface protection film 28 include plating metal films that are each formed from multiple layers or a single layer such as Ni/Au, Ni/Pd/Au or Sn, and an organic protective film (OSP). Further, the surface protection film 28 may be formed on both of the first surface (F1) of the wiring conductor layer 21 and the end surface (25a) of the conductor post 25 or may be formed on only one of the two. Further, surface protection films of different materials may be respectively formed on the first surface (F1) of the wiring conductor layer 21 and the end surface (25a) of the conductor post 25. For example, a metal film such as Ni/Au or Ni/Pd/Au may be formed on the first surface (F1) and an OSP may be formed on the end surface (25a).

The conductor post 25 is a columnar body that is formed on the second surface (F2) of the wiring conductor layer 21. A planar shape (cross-sectional shape in a plane parallel to the first surface (f1)) of the conductor post 25 may be any shape such as a circular, oval, square, rectangular or rhombic shape. When the conductor post 25 is formed using an electroplating method, the conductor post 25 can be formed to have any planar shape by forming an opening in a resist film in a desired shape during plating.

Further, although not illustrated in the drawings, the side surface of the conductor post 25 may be subjected to a roughening treatment that roughens the surface. By roughening the side surface of the conductor post 25, a so-called anchor effect is achieved, and the adhesion between the conductor post 25 and the resin insulating layer 30 is improved. A method of the roughening treatment is not particularly limited. For example, a soft etching treatment, a blackening (oxidation)-reduction treatment, or the like, may be adopted. Further, the side surface of the wiring conductor layer 21 and the second surface (F2) except a portion where the conductor post 25 is formed may also be subjected to the same roughening treatment as the side surface of the conductor post 25. In this case, the adhesion between the wiring conductor layer 21 and the resin insulating layer 30 can be improved.

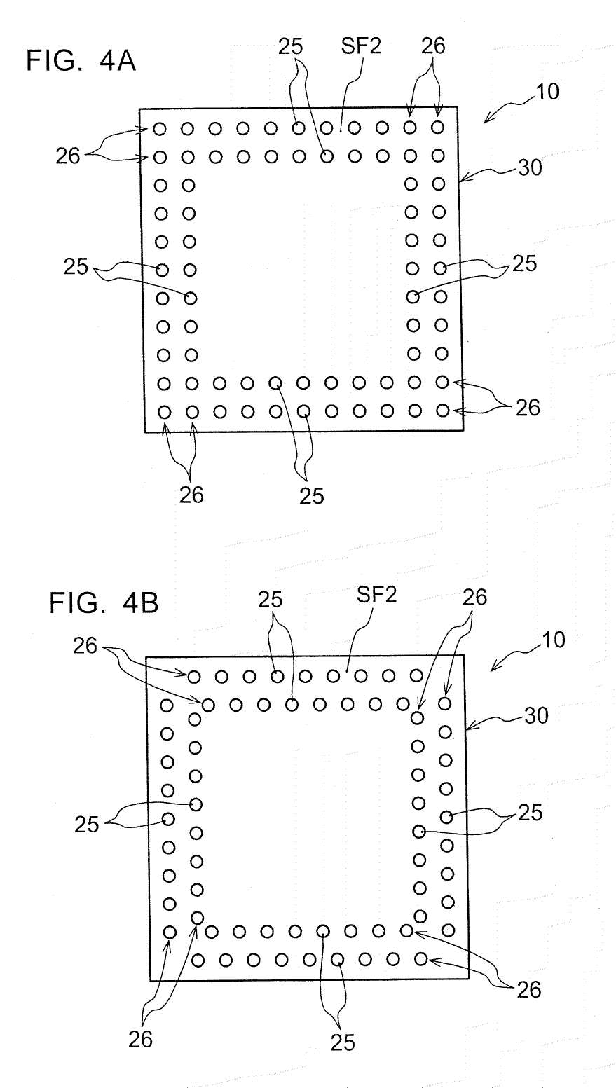

FIGS. 4A and 4B illustrate examples of formation of conductor posts 25 of the wiring board 10 of the present embodiment on the second surface (SF2) of the resin insulating layer 30. In the example illustrated in FIG. 1, one conductor post 25 is formed on each of both sides of a region where the second pattern (21b) is positioned. However, the number of the conductor posts 25 that are formed and the positions where the conductor posts 25 are formed are not limited to those illustrated in FIG. 1. For example, as illustrated in FIG. 4A, it is also possible that two conductor post rows 26 are positioned in parallel and formed along each side of the wiring board 10, the conductor post rows 26 being each formed by positioning side by side multiple conductor posts 25 in one direction. It is also possible that three or more conductor post rows 26 are positioned in parallel. For example, it is also possible that the conductor posts 25 are formed in a lattice pattern over the entire second surface (SF2) of the resin insulating layer 30. The first pattern (21a) is formed on the first surface (SF1) of the resin insulating layer 30 at positions corresponding to the positions at which the conductor posts 25 are positioned on the second surface (SF2).

Further, as illustrated in FIG. 4B, it is also possible that the two conductor post rows 26 that are positioned in parallel are formed such that the positions of the conductor posts 25 are shifted between the two rows in a row direction. In the example illustrated in FIG. 4B, the two conductor post rows 26, which are formed adjacent to each other and in each of which the conductor posts 25 are positioned side by side at the same pitch, are formed such that the positions of the conductor posts 25 are shifted between the two rows by a length equal to one-half of the positioning pitch in the row direction. That is, the conductor posts 25 are positioned in a zigzag pattern. In this way, by positioning the conductor posts 25 in the zigzag pattern, an interval between conductor posts 25 of adjacent conductor post rows 26 becomes wider and a state in which electrical short circuiting occurs between the conductor posts 25 is less likely to occur. Therefore, the conductor post rows 26 can be positioned in parallel at a narrower pitch. Also in the example illustrated in FIG. 4B, it is also possible that the conductor post rows 26 are formed over the entire second surface (SF2) of the resin insulating layer 30.

Next, an example of a method for manufacturing the wiring board 10 of the present embodiment is described with reference to FIG. 5A-5J.

In the method for manufacturing the wiring board 10 of the present embodiment, first, as illustrated in FIG. 5A, as starting materials, a support plate 80, a carrier copper foil (80a) and a base metal foil 81 are prepared. The carrier copper foil (80a) is laminated on both sides of the support plate 80 and is bonded to both sides of the support plate 80 by applying heat and pressure. A prepreg material or the like in a semi-cured state made of a material obtained by impregnating a core material such as a glass cloth with an insulating resin such as epoxy is preferably used for the support plate 80. However, without being limited to this, other materials may also be used. A material of the base metal foil 81 is a material that allows the wiring conductor layer 21 (to be described later) (see FIG. 5B) to be formed on a surface of the material. As the material of the base metal foil 81, a material is used that can be similarly dissolved in an etching solution in which the material of the wiring conductor layer 21 and the material of conductor post 25 (to be described later) (see FIG. 5D) dissolve, and a copper foil having a thickness of 1.5-3 μm is preferably used. However, the material of the base metal foil 81 is not limited to the copper foil. When a material different from that of the conductor post 25 (to be described later) such as a Ni foil is used, when the base metal foil (Ni foil) is removed by etching, the conductor post 25 is not dissolved, and a protruding height of the conductor post 25 can be maintained. Further, as the carrier copper foil (80a), for example, a copper foil having a thickness of 15-30 μm, preferably 18 μm, is used. However, the carrier copper foil (80a) is not limited to have these thicknesses, but may also have other thicknesses.

A method for bonding the carrier copper foil (80a) and the base metal foil 81 is not particularly limited. However, for example, substantially entire sticking surfaces of the two may be bonded by a thermoplastic adhesive (not illustrated in the drawings) that allows easy peeling, or, the two may be bonded by an adhesive, or by ultrasonic connection, in a margin portion in a vicinity of an outer periphery where a conductor pattern of the wiring conductor layer 21 (to be described later) (see FIG. 5B) is not provided. Further, the carrier copper foil (80a) and the base metal foil 81 may be bonded to each other before the carrier copper foil (80a) is bonded to the support plate 80. However, without being limited to this, for example, it is also possible that a double-sided copper-clad laminated plate is used for the support plate 80; a copper foil on surface of the double-sided copper-clad laminated plate is used as the carrier copper foil (80a); and the single base metal foil 81 is bonded to the copper foil using the above-described method or the like.

In FIG. 5A-5H, an example of an manufacturing method is illustrated in which the base metal foil 81 is bonded to surfaces on both sides of the support plate 80 and the wiring conductor layer 21, the conductor post 25 and the resin insulating layer 30 are formed on each of the surfaces. Such a manufacturing method is preferable in that two wiring boards each including the wiring conductor layer 21, the conductor post 25 and the like are simultaneously formed. However, it is also possible that the wiring conductor layer 21 and the like are formed on only one side of the support plate 80. Further, it is also possible that wiring conductor layers having mutually different circuit patterns are respectively formed on the two sides of the support plate 80. The following description is given with reference to an example in which the same circuit patterns are formed on both sides of the support plate 80. Therefore, the description is given regarding only one side, and the description regarding the other side and reference numeral symbols for the other side in the drawings are omitted.

As illustrated in FIG. 5B, the wiring conductor layer 21 is formed on the base metal foil 81. A method for forming the wiring conductor layer 21 is not particularly limited. However, for example, an electroplating method is used. Specifically, first, a resist material (not illustrated in the drawings) is applied to or laminated on an entire surface of the base metal foil 81 and is patterned. Thereby, plating resist film (not illustrated in the drawings) is formed in a predetermined region other than a portion where the wiring conductor layer 21 is formed. Next, a plating layer is formed, for example, by electroplating using the base metal foil 81 as a lead layer of electroplating on the base metal foil 81 where the plating resist film is not formed. Thereafter, the plating resist film is removed. As a result, as illustrated in FIG. 5B, the wiring conductor layer 21 (in which the first pattern (21a) and the second pattern (21b) are formed) is formed in a predetermined circuit pattern on the base metal foil 81. The wiring conductor layer 21 is preferably formed of the same material as that of the conductor post (to be described later), and is preferably formed of copper. Further, the wiring conductor layer 21 can be preferably formed to have a thickness of 10-30 μm. However, the present invention is not limited to this.

Next, the conductor post 25 is formed on the first pattern (21a) of the wiring conductor layer 21. Specifically, first, as illustrated in FIG. 5C, a plating resist film 85 is formed on a surface (second surface (F2)) of the wiring conductor layer 21 on a side opposite to a surface (first surface (F1)) that is in contact with the base metal foil 81, excluding a portion where the conductor post 25 (see FIG. 5D) is formed, and on the base metal foil 81 that is exposed without being covered by the wiring conductor layer 21. The plating resist film 85 is formed to have a thickness of at least about 50-150 μm. Next, a plating layer 250 is formed, for example, by electroplating using the base metal foil 81 as a lead layer of electroplating on the first pattern (21a) where the plating resist film 85 is not formed. Thereafter, the plating resist film 85 is removed. As a result, as illustrated in FIG. 5D, the conductor post 25 made of the plating layer is formed on the second surface (F2) of the first pattern (21a), the plating layer being formed by electroplating. The conductor post 25 is preferably formed of the same material as that of the wiring conductor layer 21, and is preferably formed of copper. Further, the conductor post 25 can be preferably formed to have a thickness of 50-150 μm. However, the present invention is not limited to this.

After the conductor post 25 is formed, it is preferable that, in order to enhance the adhesion to the resin insulating layer 30 (to be described later), the side surface (25c) and the end surface (25a) of the conductor post 25, and the side surface of the wiring conductor layer 21 and the portion of the second surface (F2) where the conductor post 25 is not formed, be subjected to a roughening treatment. A method of the roughening treatment is not particularly limited. However, for example, a soft etching treatment, a blackening (oxidation)-reduction treatment, or the like, may be adopted. The surfaces that are roughened are preferably processed to have a surface roughness of 0.1-1 μm in arithmetic average roughness. Further, in the case where the roughening treatment is performed, between the removal of the plating resist film 85 and the roughening treatment, in order to stabilize the roughening, an annealing treatment that allows electroplating copper crystals to grow may be performed.

Next, the resin insulating layer 30 (see FIG. 5F) that covers the wiring conductor layer 21 and the conductor post 25 is formed. Specifically, first, as illustrated in FIG. 5E, a sheet-like or film-like insulating material 33 is laminated on the conductor post 25, and is pressed toward the support plate 80 side and is heated. Due to the heating, the insulating material 33 is softened, and flows into between the first pattern (21a) and the second pattern (21b), between the second patterns (21b) and between the conductor posts 25, and solidifies in a semi-cured state. Thereafter, the insulating material 33 is completely cured by being further heated and, as illustrated in FIG. 5F, the resin insulating layer 30 is formed that covers the side surface of the first pattern (21a) and the portion of the second surface (F2) of the first pattern (21a) where the conductor post 25 is not formed, the side surface and the second surface (F2) of the second pattern (21b), and the entire side surface and end surface (25a) of the conductor post 25. Such a method in which the sheet-like or film-like insulating material is laminated to form the resin insulating layer 30 is preferable in that the resin insulating layer 30 can be manufactured using common equipment for manufacturing a wiring board. After the resin insulating layer 30 is formed, preferably, buffing is performed and burrs that occur during the formation of the resin insulating layer 30 are removed.

As illustrated in FIG. 5G, a surface (second surface (SF2)) of the resin insulating layer 30 on an opposite side of the base metal foil 81 side is polished by buffing, CMP (Chemical Mechanical Polishing) or the like until the front end of the conductor post 25 is exposed to the second surface (SF2).

Next, for example, spraying of a polishing agent by sandblasting or the like is performed to the second surface (SF2) side of the resin insulating layer 30 and only a portion of the resin insulating layer 30 is removed. As a result, as illustrated in FIG. 5H, a structure is obtained in which the conductor post 25 protrudes from the second surface (SF2) of the resin insulating layer 30.

Thereafter, the support plate 80 and the carrier copper foil (80a) are separated from the base metal foil 81. Specifically, first, for example, in a state in which a half-way product (10a) of wiring boards illustrated in FIG. 5H is heated and the thermoplastic adhesive (not illustrated in the drawings) that bonds the carrier copper foil (80a) and the base metal foil 81 is softened, a force is applied to the support plate 80 and the carrier copper foil (80a) in a direction along an interface with the base metal foil 81, so that the carrier copper foil (80a) and the base metal foil 81 are pulled apart from each other. Or, as described above, when the carrier copper foil (80a) and the base metal foil 81 are bonded by an adhesive or by ultrasound connection in a margin portion of a vicinity of an outer periphery, it is also possible that the carrier copper foil (80a), the base metal foil 81 and the support plate 80 together with the resin insulating layer 30 and the like are cut on an inner peripheral side than the bonding area, and the bonding area due to the adhesive or the like is removed, and thereby, the carrier copper foil (80a) and the base metal foil 81 are separated. As a result, the half-way product (10a) of wiring boards becomes two separate half-way products. This state is illustrated in FIG. 5I. Only a half-way product (10a) of a wiring board illustrated on a lower side of the support plate 80 in FIG. 5H is illustrated in FIG. 5I.

Next, for example, the protruding portion of the conductor post 25 is covered by applying a resist (not illustrated in the drawings) thereto, and the base metal foil 81 is removed, for example, by etching or the like. As an etching solution for the etching, an etching solution that allows the materials of both the base metal foil 81 and the wiring conductor layer 21 to be dissolved is used. Even after the base metal foil 81 is completely removed, the etching process is continued such that the first surface (F1) of the wiring conductor layer 21 that is exposed to the first surface (SF1) of the resin insulating layer 30 due to the removal of the base metal foil 81 is exposed to the etching solution. Thereby, the first surface (F1) side of the wiring conductor layer 21 is etched in the same way as when the base metal foil 81 is etched. Thereafter, the resist film that covers the protruding portion of the conductor post 25 is removed. As a result, as illustrated in FIG. 5J, the first surface (F1) of the wiring conductor layer 21 is recessed relative to the first surface (SF1) of the resin insulating layer 30, and the end surface (25a) of the conductor post 25 is exposed at a position that protrudes from the second surface (SF2) of the resin insulating layer 30. When the conductor post 25 sufficiently protrudes from the second surface (SF2) of the resin insulating layer 30 due to the above-described removal of a portion of the resin insulating layer 30, resist application to the protruding portion of the conductor post 25 may be omitted. Further, as described above, when a Ni foil is used for the base metal foil 81, it is not necessary to apply a resist to the protruding portion of the conductor post 25. That is, when the base metal foil 81 is removed by etching, even when a resist is not applied to the protruding portion of the conductor post 25, the protruding portion of the conductor post 25 is not dissolved and the protruding height can be maintained

After the removal of the base metal foil 81, preferably, the surface protection film 28 (see FIG. 3) is formed on the first surface (F1) of the wiring conductor layer 21 and on the end surface (25a) of the conductor post 25. The formation of the surface protection film 28 may be performed by forming multiple metal films or a single metal film such as Ni/Au, Ni/Pd/Au, Sn, or the like, using a plating method. Further, an OSP may be formed by immersion in a liquid protective material, spraying a protective material, or the like. The surface protection film may be formed on both of the first surface (F1) of the wiring conductor layer 21 and the end surface (25a) of the conductor post 25 or may be formed on only one of the two. Surface protection films of different materials may be respectively formed on the first surface (F1) of the wiring conductor layer 21 and the end surface (25a) of the conductor post 25.

Further, in addition to the formation of the surface protection film, or without forming the surface protection film, a bonding material layer (not illustrated in the drawings) made of a bonding material that bonds the conductor post 25 and an external motherboard or the like may be formed on the end surface (25a) of the conductor post 25. Solder is preferably used as a material of the bonding material layer. The bonding material layer can be formed by applying a paste-like solder or positioning solder balls and melting the solder once and then hardening the solder, or using a plating method. However, the material and the formation method of the bonding material layer are not particularly limited. Other materials and methods can also be used.

Through the above-described processes, the wiring board 10 of the present embodiment illustrated in FIG. 1 is completed. A semiconductor component (not illustrated in the drawings) may be connected on the second pattern (21b) of the completed wiring board 10. Further, the end surface (25a) of the conductor post 25 may be connected to a motherboard or the like of an electronic device or the like in which the wiring board 10 is used, or may be connected to another printed wiring board (not illustrated in the drawings) as a part of a multilayer printed wiring board.

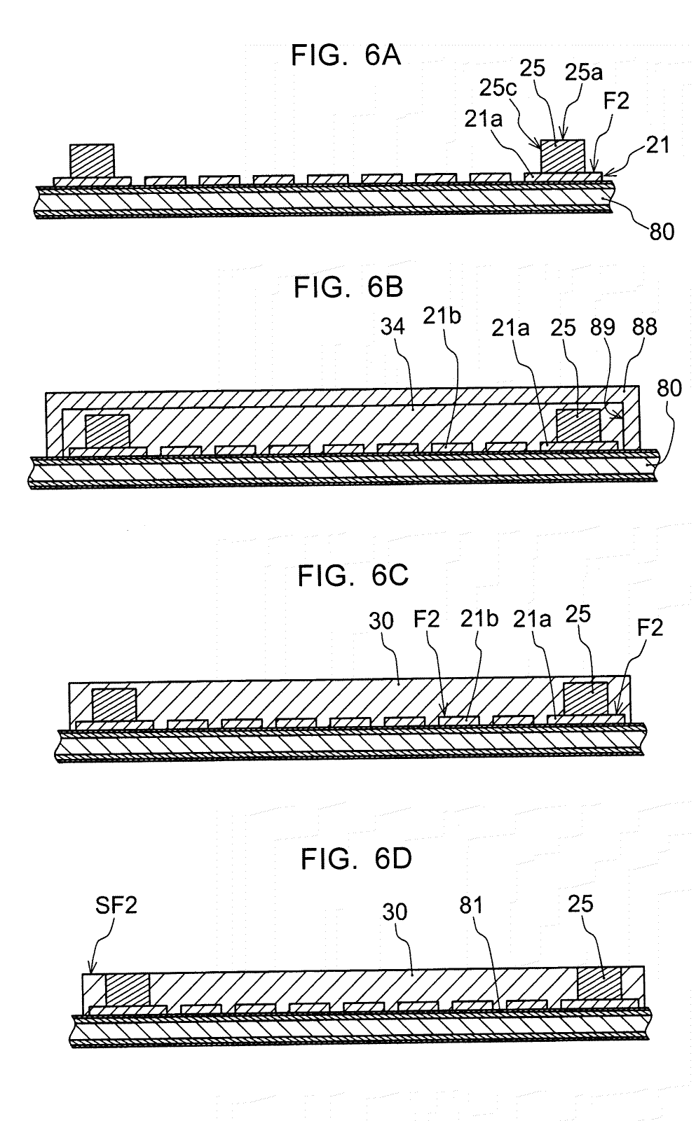

In the above description presented with reference to FIG. 5A-5J, an example of the method for manufacturing the wiring board 10 of the present embodiment is described in which the sheet-like or film-like insulating material 33 is laminated and is heated and pressed and thereby the resin insulating layer 30 is formed. However, the resin insulating layer 30 of the wiring board 10 of the present embodiment may also be formed by mold-molding, and such a method as another example of the method for manufacturing the wiring board 10 of the present embodiment (hereinafter, the example of the method for manufacturing the wiring board 10 in which the resin insulating layer 30 is formed by mold-molding is also simply referred to as the present manufacturing method) is described below with reference to FIG. 6A-6D. When the resin insulating layer 30 is formed by mold-molding, during molding, the support plate 80 is supported by a lower mold of a molding mold and is covered with an upper mold of the molding mold. Therefore, there are cases where forming the resin insulating layer 30 on both sides of the support plate 80 is difficult. Therefore, in the following description, an example is described in which the wiring board 10 is formed on only one side of the support plate 80. In FIG. 6A-6D, an example is illustrated in which the wiring conductor layer 21 and the like are formed only on the upper side of the support plate 80. However, when the resin insulating layer 30 can be formed on both sides of the support plate 80 at least sequentially one side at a time, such as when the support plate 80 can be supported by being only partially in contact with the lower mold, it is also possible that the wiring conductor layer 21 and the like are formed on both sides of the support plate 80 and the resin insulating layer 30 is formed on both sides of the support plate 80 by mold-molding. In the present manufacturing method, processes other than the process for forming the resin insulating layer 30 are the same as in the manufacturing method described with reference to FIG. 5A-5J. Therefore, drawings corresponding to FIG. 5A-5C and 5H-5J and description about the processes of these drawings are omitted as appropriate.

In the present manufacturing method, through the same processes as those described with reference to FIG. 5A-5C, as illustrated in FIG. 6A (same as FIG. 5D except for being single-sided), the conductor post 25 is formed on the first pattern (21a) of the wiring conductor layer 21 that is formed on one side of the support plate 80. After the conductor post 25 is formed, it is preferable that, in order to enhance the adhesion to the resin insulating layer 30 (to be described later), the side surface (25c) and the end surface (25a) of the conductor post 25, and the side surface of the wiring conductor layer 21 and the portion of the second surface (F2) where the conductor post 25 is not formed, be subjected to a roughening treatment. A method of the roughening treatment is not particularly limited. However, for example, a soft etching treatment, a blackening (oxidation)-reduction treatment, or the like, may be adopted. The surfaces that are roughened are preferably processed to have a surface roughness of 0.1-1 μm in arithmetic average roughness. Further, after the formation of the conductor post 25 and before the roughening treatment, in order to stabilize the roughening, an annealing treatment that allows electroplating copper crystals to grow may be performed.

Next, the resin insulating layer 30 (see FIG. 6C) is formed. Specifically, first, as illustrated in FIG. 6B, a mold 88 having a cavity 89 is set on the support plate 80. The first and second patterns (21a, 21b) and the conductor post 25 are accommodated in the cavity 89 of which an opening is closed by the support plate 80. Subsequently, a mold-molding resin 34 is injected into the cavity 89, and the cavity 89 is filled with the mold-molding resin 34. The mold-molding resin 34 solidifies in a semi-cured state. Thereafter, the mold 88 is separated from the support plate 80. The mold-molding resin 34 is completely cured by being further heated. As illustrated in FIG. 6C, the resin insulating layer 30 is formed that covers the side surface of the first pattern (21a) and the portion of the second surface (F2) of the first pattern (21a) where the conductor post 25 is not formed, the side surface and the second surface (F2) of the second pattern (21b), and the entire side surface and end surface (25a) of the conductor post 25. After the resin insulating layer 30 is formed, preferably, buffing is performed and burrs that occur during the formation of the resin insulating layer 30 are removed.

Next, a surface (second surface (SF2)) of the resin insulating layer 30 on an opposite side of the base metal foil 81 side is polished by buffing, CMP or the like until the front end of the conductor post 25 is exposed to the second surface (SF2). This state after the polishing is illustrated in FIG. 6D. This state has the same structure as that illustrated in FIG. 5G.

Thereafter, through the same processes as those described with reference to FIG. 5H-5J, the wiring board 10 illustrated in FIG. 1 is completed. A method such as the present manufacturing method in which the resin insulating layer 30 is formed by mold-molding is preferable in that a material that is the same as a packaging material of a common electronic component that is packaged using a mold-molding resin can be used, and thus a stress due to a difference in thermal expansion coefficient is unlikely to occur at a bonding place or the like between the wiring board 10 and an electronic component mounted on the wiring board 10.

Further, the method for manufacturing the wiring board 10 of the present embodiment is not limited to the methods described with reference to FIG. 5A-5J and FIG. 6A-6D. The conditions, processing order and the like of the methods may be arbitrarily modified. Further, certain processes may be omitted and other processes may be added.

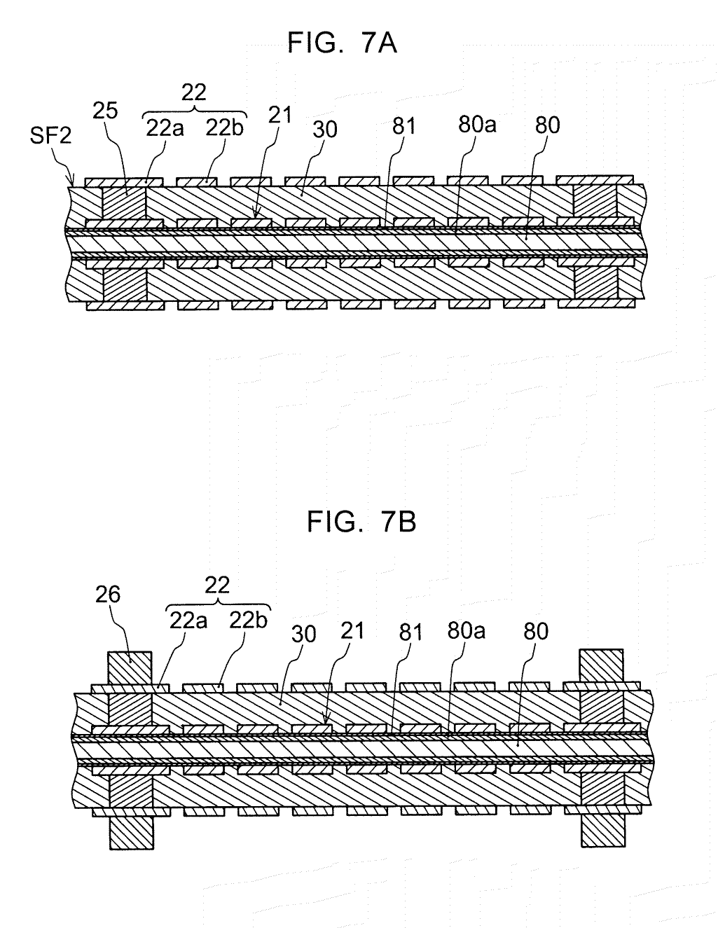

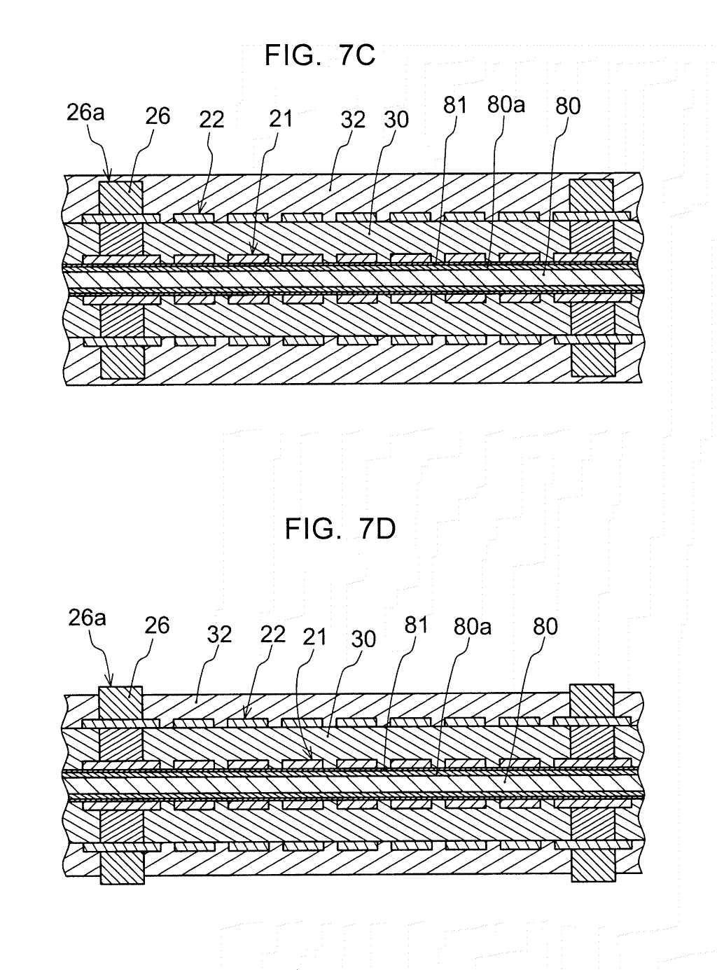

An example in which a second resin insulating layer 32 and a second wiring conductor layer 22 are further built up on the wiring board 10 that is formed as described above is illustrated in FIG. 7A-7D. That is, the wiring board is similarly manufactured to the above-described example until the above-described FIG. 5G, and manufacturing processes thereafter are illustrated in FIG. 7A-7D.

First, in the state of FIG. 5G, a metal coating (not illustrated in the drawings) is formed over the entire second surface (SF2) of the resin insulating layer 30 using a method such as electroless plating or sputtering or by pasting a metal foil, and the second wiring conductor layer 22 is formed using an electroplating method similar to the method illustrated in FIG. 5B. Thereafter, an exposed portion of the metal coating (not illustrated in the drawings) is removed by etching and thereby, as illustrated in FIG. 7A, the second wiring conductor layer is formed.

Next, as illustrated in FIG. 7B, a second conductor post 26 is formed. Similar to the example illustrated in the above-described FIG. 5C-5D, the second conductor post 26 is formed by forming a resist film that exposes only a place where the second conductor post 26 is to be formed and by using an electroplating method or the like.

Thereafter, as illustrated in FIG. 7C, the second resin insulating layer 32 is formed. The method for forming the second resin insulating layer 32 is also the same as the method illustrated in FIG. 5E-5F or the method illustrated in FIG. 6B-6C.

Thereafter, as illustrated in FIG. 7D, polishing is performed until the second conductor post 26 is exposed from the second resin insulating layer 32, and the second resin insulating layer 32 is partially removed. That is, similar to the processes illustrated in FIG. 5G-5H, polishing is performed until an end surface (26a) of the second conductor post 26 is exposed, and thereafter, only the second resin insulating layer 32 is partially removed. As a result, as illustrated in FIG. 7D, the end surface (26a) of the second conductor post 26 protrudes from the second resin insulating layer 32. When build-up layers are further formed, in the state illustrated in FIG. 5G in which the end surface (26a) of the second conductor post 26 and the second resin insulating layer 32 are flush with each other prior to making the end surface (26a) of the second conductor post 26 to protrude from the second resin insulating layer 32, by repeating processes of FIG. 7A-7C, a desired number build-up layers can be formed.

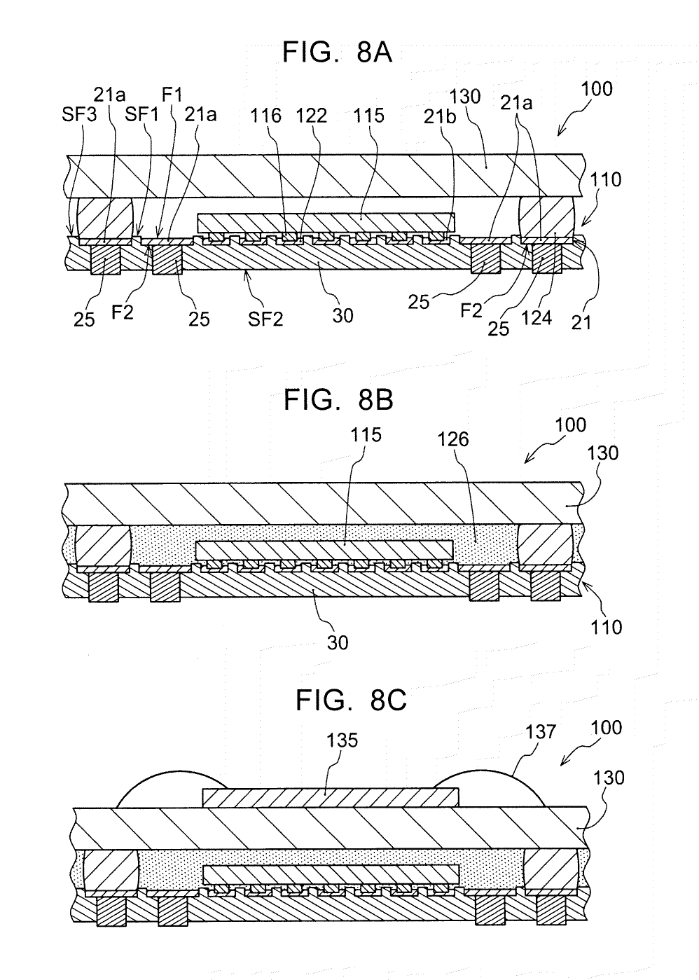

Next, a semiconductor package of an embodiment of the present invention is described with reference to the drawings. As illustrated in FIG. 8A, a semiconductor package 100 of the present embodiment includes a printed wiring board 110 and a substrate 130. A first semiconductor component 115 is mounted on a surface (SF3) of the printed wiring board 110. The substrate 130 is mounted on the surface (SF3) of the printed wiring board 110. Preferably, the printed wiring board of which an example is illustrated in FIG. 1 is used as the printed wiring board 110. An example of this is illustrated in FIG. 8A. Therefore, most of structural components of the printed wiring board 110 illustrated in FIG. 8A are the same as those of the printed wiring board 10 illustrated in FIG. 1, and such structural components are indicated using the same reference numeral symbols and detailed description thereof is omitted. However, the printed wiring board 110 is not limited to the printed wiring board 10 illustrated in FIG. 1, but may incorporate various modifications and variations with respect to the respective structural components as indicated in the above description of the printed wiring board 10.

As illustrated in FIG. 8A, similar to the printed wiring board 10 illustrated in FIG. 1, the printed wiring board 110 has the wiring conductor layer 21 that is embedded in the resin insulating layer 30 such that the first surface (F1) of the wiring conductor layer 21 is exposed to the first surface (SF1) of the resin insulating layer 30, and the first pattern (21a) and the second pattern (21b) are formed in the wiring conductor layer 21. The conductor post 25 is formed on the second surface (F2) on the opposite side of the first surface (F1) of the first pattern (21a), and the resin insulating layer 30 covers the side surface of the conductor post 25. The first surface (F1) of the wiring conductor layer 21 is recessed relative to the first surface (SF1) of the resin insulating layer 30. The end surface (25a) of the conductor post 25 on the opposite side of the wiring conductor layer 21 is exposed to the second surface (SF2) side of the resin insulating layer 30 and protrudes from the second surface (SF2).

In the example illustrated in FIG. 8A, two first patterns (21a) are formed on each of left and right outer sides in FIG. 8A of the region where the second pattern (21b) is formed, and a conductor post 25 is formed on the second surface (F2) of each of the first patterns (21a). Also in the semiconductor package 100 of the present embodiment, the conductor posts 25 may be positioned in one conductor post row or in multiple conductor post rows in one direction along an outer periphery of the printed wiring board 110 and, as described above, may also be positioned over the entire second surface (SF2) of the resin insulating layer 30,

The substrate 130 has a bump 124 on a surface on the printed wiring board 110 side, and the bump 124 is connected to a first pattern (21a) that is formed in the wiring conductor layer 21. In the example illustrated in FIG. 8A, the bump 124 is connected to the first pattern (21a) formed on an outer peripheral side of the printed wiring board 110.

Further, the first semiconductor component 115 is positioned in a space secured between the printed wiring board 110 and the substrate 130, depending on a height of the bump 124. Further, the first semiconductor component 11 has electrodes 116. The electrodes 116 are connected by a bonding material 122 to the second pattern (21b) formed in the wiring conductor layer 21.

The semiconductor package 100 of the present embodiment includes the printed wiring board 110 that has the same structure as above-described printed wiring board 10 of which an embodiment is illustrated in FIG. 1. Therefore, as described above, even when the first and second patterns (21a, 21b) of the wiring conductor layer 21 and the like are formed at fine pitches, adhesion to the resin insulating layer 30 can be easily maintained. Further, on the first surface (SF1) of the printed wiring board 110, short circuiting between connecting parts that connect to the first semiconductor component 115 can be prevented. Further, even when the wiring patterns are formed at fine pitches, highly reliable electrical connection between the conductor post 25 and the wiring conductor layer 21 can be obtained.

The structure and material of the substrate 130 are not particularly limited. For the substrate 130, a printed wiring board that is formed by an interlayer resin insulating layer made of a resin material and conductor layer made of a copper foil or the like, a wiring board obtained by forming a conductor film on a surface of an insulating substrate made of an inorganic material such as alumina or aluminum nitride, and a motherboard substrate which may be manufactured using a method described in FIG. 8-13 of International Publication No. WO/2011/122246 may be utilized. The entire contents of this publication are incorporated herein by reference. Further, the first semiconductor component 115 is also not particularly limited. Any semiconductor component, such as a microcomputer, a memory, and an ASIC, can be used as the first semiconductor component 115.

The materials for the bonding material 122 and the bump 124 are also not particularly limited. Any conductive material, preferably, metal such as solder, gold and copper can be used. Further, it is also possible that, without using the bonding material 122, the electrodes 116 of the first semiconductor component 115 and the second pattern (21b) are connected by forming an inter-metal junction between the two by applying heat, pressure and/or vibration.

FIG. 8B illustrates an example in which a space between the printed wiring board 110 and the substrate 130 of the semiconductor package 100 illustrated in FIG. 8A is filled with a mold resin 126. In this way, when the space is filled with the mold resin 126, there are advantages such as that the first semiconductor component 115 is protected from a mechanical stress, and that the behavior of the printed wiring board 110 due to ambient temperature variation is limited, a stress that occurs in a portion connecting to the first semiconductor component 115 is reduced and connection reliability is improved. The material for the mold resin 126 is not particularly limited. However, for example, a material that has a thermal expansion coefficient close to that of the first semiconductor component 115 and/or that of the resin insulating layer 30 and has good insulation performance is used. Preferably, as the mold resin 126, a thermosetting epoxy resin containing a suitable amount of filler such as silica is used. A method for filling the space with the mold resin 126 is not particularly limited. For example, the filling may be performed by transfer molding in a mold (not illustrated in the drawings), or by injecting a liquid resin and thereafter applying heat to perform curing.

FIG. 8C illustrates an example in which a second semiconductor component 135 is mounted on the substrate 130 of the semiconductor package 100 illustrated in FIG. 8B. As illustrated in FIG. 8C, electrodes (not illustrated in the drawings) that are provided on one surface of the second semiconductor component 135 are connected to the substrate 130 by a bonding wire 137, or, the connection may be performed using a flip-chip mounting method by inverting the second semiconductor component 135 so that the surface on which the electrodes are provided faces downward. In this way, by making the semiconductor package in a package-on-package structure in which the second semiconductor component 135 is mounted, a size in a plan view can be reduced and a sophisticated semiconductor device can be provided.

In a printed wiring board used in a package of a semiconductor device, when a desired electrical circuit is formed on one side alone, a wiring pattern that includes connecting parts for connecting to a semiconductor component is formed only on one side, and only connecting parts for connecting to a motherboard may be provided on the other side.

As a semiconductor component becomes sophisticated in recent years, there is a tendency that electrodes of the semiconductor component are formed at a narrow pitch and the number of the electrodes is also increasing. Therefore, wirings of a conductor pattern in a printed wiring board are formed at a fine pitch. In particular, when a wiring pattern is formed on only one side of a printed wiring board in order to achieve cost reduction of the printed wiring board, a fine-pitch wiring pattern may be formed so that a desired circuit can be formed on only one side of the printed wiring board. Further, in such a printed wiring board in which a semiconductor component is connected, connecting parts that connect to a motherboard are also formed at a narrow pitch.

In a circuit substrate, a conductor layer may be formed on a surface of an insulating substrate. Therefore, when a wiring pattern is formed at a fine pitch, there is a risk that a contact area between the wiring pattern and the insulating substrate is reduced and adhesion is decreased. Further, there is also a risk that bonding materials flow between connecting parts of a semiconductor component and become in contact with each, causing short circuiting to occur. Further, in the circuit substrate, a conductor post may be formed by irradiating laser to an insulating hard substrate to drill a hole and filling the hole with a conductive paste. Therefore, the hole has a shape that is large on the drilling side and is small on the connecting conductor circuit side. That is, the hole has tapered cross-sectional shape. A connecting part that connects to the circuit substrate has a small area. In addition, there is a possibility that residues of a processed insulating material remain in the hole. Further, since the conductor post is formed by filling the hole with the paste, when conductor posts are formed at a fine pitch and become thin, there is a possibility connection reliability is further reduced.

A printed wiring board according to an embodiment of the present invention allows good adhesion to be maintained between a conductor layer and an insulating layer, allows short circuiting between adjacent connecting parts to be suppressed both for connecting parts that connect to a semiconductor component or the like on one side and for connecting parts that connect to a motherboard or the like on the other side, and allows connection reliability between a conductor post and the conductor layer to be increased, the conductor post being for connecting the conductor layer and the motherboard or the like on the other side, even when a wiring pattern is formed at a fine pitch. Another embodiment of the present invention is a method for manufacturing such a printed wiring board, and yet another embodiment of the present invention is a semiconductor package containing such a printed wiring board.

A printed wiring board according to an embodiment of the present invention includes: a wiring conductor layer that has a first surface and a second surface that is on an opposite side of the first surface; a conductor post that is formed on the second surface of the wiring conductor layer; and a resin insulating layer that has a first surface and a second surface that is on an opposite side of the first surface, embeds the wiring conductor layer such that the first surface of the wiring conductor layer is exposed to the first surface of the resin insulating layer, and covers a side surface of the conductor post. The first surface of the wiring conductor layer is recessed relative to the first surface of the resin insulating layer. An end surface of the conductor post on an opposite side of the wiring conductor layer protrudes from the second surface side of the resin insulating layer.

A semiconductor package according to an embodiment of the present invention includes a printed wiring board and a substrate. A first semiconductor component is mounted on a surface of the printed wiring board. The substrate is mounted on the surface of the printed wiring board. The printed wiring board includes a wiring conductor layer that has a first surface and a second surface that is on an opposite side of the first surface; a conductor post that is formed on the second surface of the wiring conductor layer; and a resin insulating layer that has a first surface and a second surface that is on an opposite side of the first surface, embeds the wiring conductor layer such that the first surface of the wiring conductor layer is exposed to the first surface of the resin insulating layer, and covers a side surface of the conductor post. The first surface of the wiring conductor layer is recessed relative to the first surface of the resin insulating layer. An end surface of the conductor post on an opposite side of the wiring conductor layer protrudes from the second surface side of the resin insulating layer. The substrate has a bump on a surface on the printed wiring board side. The bump is connected to the wiring conductor layer.

A method for manufacturing a printed wiring board according to an embodiment of the present invention includes: forming a conductor layer that has a predetermined pattern on at least one side of a support plate; forming a conductor post on the conductor layer; forming an resin insulating layer that covers an entire exposed surface of the conductor layer and covers at least an entire side surface of the conductor post; removing a surface layer portion of the resin insulating layer on an opposite side of the conductor layer to allow an end part of the conductor post on the surface layer portion side to protrude from a surface of the resin insulating layer; and separating the support plate and the conductor layer from each other.

According to an embodiment of the present invention, the wiring conductor layer is embedded in the resin insulating layer on the first surface side. Therefore, a contact area between the wiring conductor layer and the resin insulating layer is increased. As a result, even when a wiring pattern is formed at a fine pitch in the wiring conductor layer, the adhesion to the resin insulating layer can be maintained. Further, the conductor post is formed on the second surface of the wiring conductor layer and a surrounding area of the conductor post is covered by the resin insulating layer. Therefore, the conductor post does not have a structure that is formed by drilling a hole in the resin insulating layer and filling the hole with a wiring conductor layer. Therefore, the conductor post is formed as a substantially vertical column, and a cross-sectional area of a connecting part of the conductor post that connects to the wiring conductor layer is substantially the same as a cross-sectional area on an opposite side. As a result, even when conductor posts are formed at a fine pitch and become thin, a sufficient area of the connecting part that connects to the conductor layer can be secured. In addition, since the conductor post is directly formed on the surface of the conductor layer, without having residues of the resin insulating layer interposed therebetween, the connection reliability between the conductor layer and the conductor post can be significantly improved.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a wiring conductor layer having a first surface;
a plurality of conductor posts formed on a second surface of the wiring conductor layer on an opposite side with respect to the first surface; and
a resin insulating layer embedding the wiring conductor layer such that the first surface of the wiring conductor layer is recessed with respect to a first surface of the resin insulating layer and exposed on the first surface of the resin insulating layer and covering side surfaces of the conductor posts such that an end surface of each of the conductor posts is protruding from a second surface of the resin insulating layer on an opposite side with respect to the first surface of the resin insulating layer.

2. The printed wiring board according to claim 1, wherein the conductor posts and the resin insulating layer are formed such that a distance between the end surface of each of the conductor posts and the second surface of the resin insulating layer is in a range of from 1 μm to 15 μm, and the wiring conductor layer and the resin insulating layer are formed such that a distance between the first surface of the resin insulating layer and the first surface of the wiring conductor layer is in a range of from 0.1 μm to 5 μm.

3. The printed wiring board according to claim 1, wherein the conductor posts and the resin insulating layer are formed such that a distance between the end surface of each of the conductor posts and the second surface of the resin insulating layer is in a range of from 3 μm to 10 μm, and the wiring conductor layer and the resin insulating layer are formed such that a distance between the first surface of the resin insulating layer and the first surface of the wiring conductor layer is in a range of from 0.1 μm to 5 μm.

4. The printed wiring board according to claim 1, wherein the plurality of conductor posts comprises electrically plated copper.

5. The printed wiring board according to claim 1, wherein each of the conductor posts has a height which is in a range of from 50 μm to 150 μm, and the wiring conductor layer has a thickness which is in a range of from 10 μm to 25 μm.

6. The printed wiring board according to claim 1, wherein each of the conductor posts has one of a circular, oval, square, rectangular or rhombic cross-sectional shape with respect to a plane parallel to the first surface of the wiring conductor layer.

7. The printed wiring board according to claim 1, wherein the resin insulating layer comprises a resin material having a thermal expansion coefficient which is in a range of from 6 ppm/° C. to 25 ppm/° C. and an elastic modulus which is in a range of from 5 GPa to 30 GPa.

8. The printed wiring board according to claim 1, wherein the resin insulating layer comprises an epoxy resin material including an inorganic filler in an amount of from 30% by weight to 80% by weight.

9. The printed wiring board according to claim 1, wherein each of the side surfaces of the conductor posts comprises a roughened surfaces formed by roughening treatment.

10. The printed wiring board according to claim 1, wherein the second surface of the wiring conductor layer comprises a roughened surface formed by roughening treatment, and the wiring conductor layer has a side surface comprising a roughened surface formed by roughening treatment.

11. The printed wiring board according to claim 1, wherein each of the conductor posts has a surface protection film formed on the end surface of each of the conductor posts.

12. The printed wiring board according to claim 1, wherein the wiring conductor layer has a surface protection film formed on the first surface of the wiring conductor layer such that the surface protection film of the wiring conductor layer comprises a material which is different form a material forming the surface protection film of the conductor posts.

13. The printed wiring board according to claim 1, further comprising:
a bonding material layer formed on the end surface of each of the conductor posts.

14. The printed wiring board according to claim 1, further comprising:
a bonding material layer comprising solder and formed on the end surface of each of the conductor posts.

15. The printed wiring board according to claim 1, wherein the plurality of conductor posts is arrayed such that at least two rows comprising at least conductor posts are positioned in parallel and that the conductor posts are positioned in one of a zigzag pattern and a lattice pattern.

16. The printed wiring board according to claim 2, wherein the plurality of conductor posts comprises electrically plated copper, each of the conductor posts has a height which is in a range of from 50 μm to 150 μm, and the wiring conductor layer has a thickness which is in a range of from 10 μm to 25 μm.

17. A semiconductor package, comprising:
a printed wiring board;
a first semiconductor component mounted on a surface of the printed wiring board; and
a substrate mounted on the surface of the printed wiring board and having a bump structure formed on a surface of the substrate facing the printed wiring board,
wherein the printed wiring board comprises a wiring conductor layer having a first surface, a plurality of conductor posts formed on a second surface of the wiring conductor layer on an opposite side with respect to the first surface, and a resin insulating layer embedding the wiring conductor layer such that the first surface of the wiring conductor layer is recessed with respect to a first surface of the resin insulating layer and exposed on the first surface of the resin insulating layer and covering side surfaces of the conductor posts such that an end surface of each of the conductor posts is protruding from a second surface of the resin insulating layer on an opposite side with respect to the first surface of the resin insulating layer, and the bump structure of the substrate is connected to the wiring conductor layer of the printed wiring board.

18. The semiconductor package according to claim 17, further comprising:
a mold resin structure comprising a mold resin material filling a space formed between the substrate and the printed wiring board such that the mold resin material is covering the first semiconductor component positioned in the space formed between the substrate and the printed wiring board.

19. The semiconductor package according to claim 17, further comprising:
a second semiconductor component mounted on the substrate.

20. A method for manufacturing a printed wiring board, comprising:
forming a conductor layer comprising a pattern on a support plate;
forming a conductor post on the conductor layer;
forming a resin insulating layer on the conductor layer such that the resin insulating layer covers an entire exposed surface of the conductor layer and at least an entire side surface of the conductor post;
removing a surface layer portion of the resin insulating layer on an opposite side with respect to the conductor layer such that an end portion of the conductor post protrudes from a surface of the resin insulating layer; and
separating the support plate from the conductor layer.
